(19) United States
(12) Patent Application Publication
(10) Pub. No.: US 2014/0167200 A1
(43) Pub. Date: Jun. 19, 2014

(54) PHOTODETECTOR AND METHOD FOR FORMING THE SAME

(71) Applicant: Agency for Science, Technology and Research, Singapore (SG)

(72) Inventors: Fei Sun, Singapore (SG); Ning Duan, Singapore (SG); Patrick Guo-Qiang Lo, Singapore (SG)

(73) Assignee: Agency for Science, Technology and Research, Singapore (SG)

(21) Appl. No.: 14/133,889

(22) Filed: Dec. 19, 2013

(30) Foreign Application Priority Data
Dec. 19, 2012 (SG) 201209367-0

(51) Int. Cl. H01L 27/144; H01L 31/18

(52) U.S. Cl. CPC H01L 27/144; H01L 31/18
USPC 257/443; 438/73

(57) ABSTRACT

According to embodiments of the present invention, a photodetector is provided. The photodetector includes a substrate having a first side and a second side opposite to the first side, the substrate being adapted to receive light incident on the photodetector on the first side of the substrate, a plurality of cells formed in the substrate, and at least one trench defined by a first sidewall and a second sidewall, wherein a spacing between the first sidewall and the second sidewall increases in a direction from the first side of the substrate towards the second side, wherein a respective trench of the at least one trench is arranged in between adjacent cells of the plurality of cells. According to further embodiments of the present invention, a method for forming a photodetector is also provided.

### CROSS-REFERENCE TO RELATED APPLICATION

This application claims the benefit of priority of Singapore patent application No. 201209367-0, filed 19 Dec. 2012, the content of it being hereby incorporated by reference in its entirety for all purposes.

### TECHNICAL FIELD

Various embodiments relate to a photodetector and a method for forming the photodetector.

### BACKGROUND

Typical silicon (Si) photodetectors include, for example, avalanche photodiodes (APDs), PIN photodiodes and the like. Si photodetectors have been used in a wide variety of applications, and have found more and more applications in light detection and image sensing in recent years. The band structure of Si has made it a very suitable material for detection of visible light. By means of scintillators, X-rays or γ-rays can be converted to low energy photons with visible wavelengths. Thus, the application of Si photodetectors is not only limited to the detection of visible light, but may also be extended to the area of radiation detection. Benefiting from the highly developed Si processing technologies and the modern fabrication facilities for batch-processing in the semiconductor industry, Si photodetectors have many advantages over their conventional counterparts, such as compactness, robustness, fast response, magnetic field insensitivity and low fabrication cost.

An array of Si photodetector cells can be used for photon detection over a large area in 2D or 3D imaging technology. Silicon Photomultiplier (SiPM) and CMOS (complementary metal-oxide-semiconductor) image sensors are two examples of Si photodetector arrays. Photon detection efficiency (PDE) and crosstalk property are two main considerations in a photodetector array. PDE indicates the detection sensitivity of the array, while crosstalk property relates closely to the image quality that is obtained. However, there is a contradiction between PDE and crosstalk and a trade-off is required between these two parameters.

FIG. 1 shows a schematic cross-sectional view of a cell 102a of a part of a silicon photomultiplier (SiPM) device 100 of prior art. The SiPM cell 102a has a SACM (Separation of Absorption, Charge, Multiplication) structure. The SiPM cell 102a includes a diode (Diode 1) 101a, which includes a detection window 104, and an active region 106 that is highly doped (p+ region), formed in a silicon (Si) substrate 140. The diode 101a further includes a lightly doped (p− region) region 142 formed in the substrate 140. The SiPM cell 102a further includes a quenching resistor 108 electrically coupled to the active region 106 via a metal wire 110a. The SiPM cell 102a further includes a passivation or insulating layer (e.g. an oxide layer) 111. Another metal wire 110b is provided electrically coupled to the active region 106.

Also shown in FIG. 1 are diodes corresponding to respective adjacent SiPM cells 102b, 102c. For example, a second cell 102b having a second diode (Diode 2) 101b, with its corresponding p+ region (active region) 152, p− region 154, metal wire 156 and insulating layer (e.g. an oxide layer) 157, is shown to the right side of the diode 101a, while a third cell 102c having a third diode (Diode 3) 101c, with its corresponding p+ active region 162, p− region 164, quenching resistor 166, metal wire 168 and insulating layer (e.g. an oxide layer) 170, is shown to the left side of the diode 101a.

The SiPM device 100 includes a common electrode 174 formed in the substrate 140, opposite to the active p+ regions 106, 152, 162. The common electrode 174 is highly doped, of a conductivity type opposite to that of the p+ regions 106, 152, 162, i.e. the common electrode 174 is an n+ region. Using the diode 101a as an example, a diode is therefore formed between the p+ region 106 and the n+ common electrode 174. The common electrode 174 is shared by the diode 101a, the second diode 101b and the third diode 101c. The SiPM device 100 further includes a metal layer or wire 176 adjacent to the common electrode 174. The remaining portion 112 of the substrate 140 may be intrinsic or undoped.

The individual diodes 101a, 101b, 101c are serially connected to neighboring poly-Si resistors 108, 166 by metal wires 110a, 168. All cells, including cells 102a, 102b, 102c, of the SiPM device 100 may be connected in parallel by a metal bus line (not shown), forming one terminal of the SiPM device 100. The other terminal of the device 100, being the common electrode 174, is connected to the substrate 140 and shared by all the cells, including cells 102a, 102b, 102c, serving as the other electrode in the diodes 101a, 101b, 101c.

As can be seen from FIG. 1, isolation trenches 120a, 120b are introduced between adjacent cells 102a, 102b, 102c to reduce crosstalk between each other. The crosstalk mainly originates from photon scattering or photocarrier diffusion. The trench 120a is provided between the adjacent cells 102a, 102b having respective diodes 101a, 101b, where the trench 120a includes an insulating layer (e.g. an oxide layer) 111 that at least substantially surrounds a metal via 122a. The trench 120b is provided between the adjacent cells 102a, 102c having respective diodes 101a, 101c, where the trench 120b includes an insulating layer (e.g. an oxide layer) 170 that at least substantially surrounds a metal via 122b. The U-shaped isolation trenches or grooves 120a, 120b, which may be achieved by dry etching of the Si substrate 140, can effectively block the transfer of photons or carriers from a cell (e.g. 102a), which receives light, to its neighboring cells (e.g. 102b, 102c). Thus the crosstalk of the device 100 can be greatly reduced.

As can also be seen in FIG. 1, only part of the device surface is adopted to collect incident photons. The areas outside the detection windows 104 are assigned to accommodate the metal wires 110a, 110b, 156, 168, the poly-Si resistors 108, 166, and also the isolation trenches 120a, 120b. Therefore, photons launched in these “dead regions” (areas outside the detection window 104) are quite unlikely to be detected. The fill factor (FF) of a Si photodetector array is defined as the area ratio between the detection window (e.g. 104) and the surface of the whole device, where the detection efficiency of a SiPM device increases with its fill factor. The SiPM device 100 has a low fill factor due to the presence of the “dead regions”.

The photon detection efficiency (PDE) of a Si photodetector array is proportional to FF, as well as the quantum efficiency (QE) of the array, and may be determined using Equation 1 below,

PDE=QE×FF×P_{trigger} (Equation 1),

where P_{trigger} is the avalanche triggering probability. Thus, a detector array with a high PDE can be achieved by increasing FF and/or QE of the device.

Obviously, if no isolation trenches (e.g. 120a, 120b) are introduced, the fill factor, as well as the photon detection efficiency, will increase, at the expense of greatly increased crosstalk between adjacent cells (e.g. 102a, 102b, 102c). This is a major trade-off in the design of conventional photodetector arrays. Compromises between PDE and crosstalk have to be taken into consideration in device design for different specific applications.

Si photodetector arrays (e.g. SiPMs) have been investigated and developed by many companies and research institutions for many years, and many ideas and technologies have been adopted to increase the PDE and reduce the crosstalk of the devices. However, there remains challenges associated with conventional SiPMs, for example in terms of the dark current/dark count rate and/or the photon detection efficiency (PDE) and/or the optical loss (e.g. light absorption in a thick substrate). For example, conventional SiPMs have high dark current, high crosstalk, and low fill factor (FF). Also, during operation, some conventional SiPMs have a long recovery time, for example as a consequence of the long distance between electrodes. Therefore, the compromise between crosstalk and photon detection efficiency remains a big issue for device designs.

Furthermore, relatively complicated fabrication processes may be required to fabricate conventional SiPM devices, consequently resulting in a decrease in yield and an increase in the fabrication cost. For some conventional SiPM devices, advanced wafer bonding or epitaxial technologies will be needed to realize the thick epitaxial layers. There are also issues of poor reproducibility of the conventional SiPM devices. There are also issues related to small fabrication tolerances.

### SUMMARY

According to an embodiment, a photodetector is provided. The photodetector may include a substrate having a first side and a second side opposite to the first side, the substrate being adapted to receive light incident on the photodetector on the first side of the substrate, a plurality of cells formed in the substrate, and at least one trench defined by a first sidewall and a second sidewall, wherein a spacing between the first sidewall and the second sidewall increases in a direction from the first side of the substrate towards the second side, wherein a respective trench of the at least one trench is arranged in between adjacent cells of the plurality of cells.

According to an embodiment, a method for forming a photodetector is provided. The method may include providing a substrate having a first side and a second side opposite to the first side, the substrate being adapted to receive light incident on the photodetector on the first side of the substrate, forming a plurality of cells in the substrate, and forming at least one trench defined by a first sidewall and a second sidewall, wherein a spacing between the first sidewall and the second sidewall increases in a direction from the first side of the substrate towards the second side, wherein a respective trench of the at least one trench is arranged in between adjacent cells of the plurality of cells.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic cross-sectional view of a cell of a part of a silicon photomultiplier (SiPM) device of prior art.

FIG. 2A shows a schematic cross-sectional view of a photodetector, according to various embodiments.

FIG. 2B shows a flow chart illustrating a method for forming a photodetector, according to various embodiments.

FIG. 3A shows a schematic partial cross-sectional view of a photodetector, according to various embodiments.

FIG. 3B shows a schematic partial cross-sectional view of the photodetector of the embodiment of FIG. 3A, when light is incident on the photodetector.

FIG. 3C shows a schematic partial cross-sectional view of a photodetector, according to various embodiments.

FIG. 3D shows a schematic partial cross-sectional view of a photodetector, according to various embodiments.

FIG. 4 shows, as cross-sectional views, various processing stages of a method for forming a photodetector, according to various embodiments.

FIG. 5 shows, as cross-sectional views, various processing stages of a method for forming a photodetector, according to various embodiments.

FIG. 6 shows, as cross-sectional views, various processing stages of a method for forming a photodetector, according to various embodiments.

FIGS. 7A to 7D show respective structures used for simulation.

FIG. 8 shows a doping profile of the structure illustrated in FIG. 7A.

FIGS. 9A to 9D show the simulated light intensity distributions at a predetermined wavelength for the respective structures of FIGS. 7A to 7D.

FIG. 10A shows a plot of crosstalk results for the respective structures of FIGS. 7A to 7D.

FIG. 10B shows a plot of internal quantum efficiencies, as a function of light wavelength, for the respective structures of FIGS. 7A to 7D.

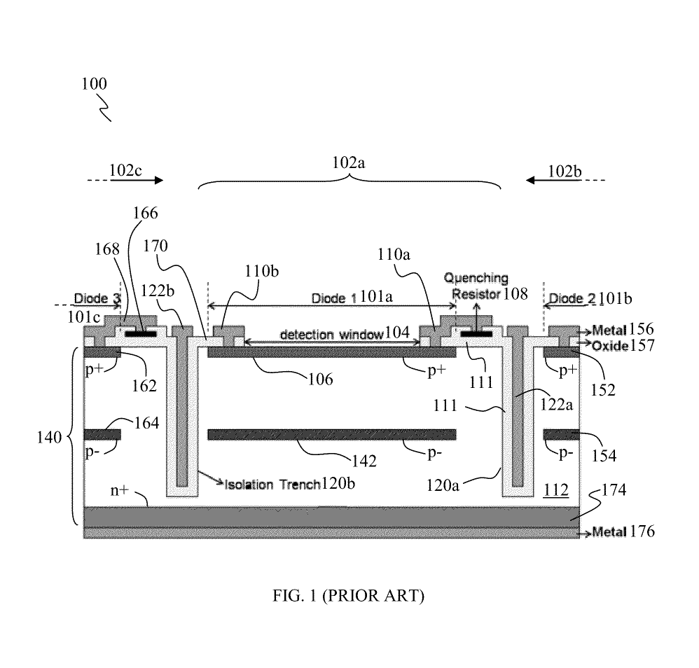

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element includes a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may relate to a photodetector. For example, various embodiments may provide a silicon (Si) photodetector array for image sensing and light detection.

Various embodiments may provide a photodetector (e.g. a semiconductor photodetector, e.g. a silicon (Si) photodetector array) with low crosstalk and high photon detection efficiency. The photodetector may be a semiconductor photomultiplier device, for example a silicon photomultiplier device (SiPM).

In various embodiments, inverted V-shaped isolation trenches (or grooves) may be introduced between neighbouring cells in the photodetector. The inverted V-grooves may greatly reduce crosstalk between adjacent cells. Furthermore, the slanted sidewalls of the V-grooves may serve as reflection mirrors for the incident light impinging on the photodetector cells. This may, for example, cause the incident light to be reflected towards a central region of each cell. Thus, the quantum efficiency of the device or photodetector may also be increased. Therefore, a high photon detection efficiency (PDE) and a low crosstalk property may be achieved simultaneously.

Various embodiments may provide a Si photodetector array structure having inverted V-grooves, which may help to increase the photon detection efficiency (PDE) and reduce the crosstalk as well. Therefore, the photodetector of various embodiments may resolve or address the contradiction between crosstalk and photon detection efficiency.

Various embodiments may provide photodetectors or photodetector arrays with inverted isolation V-grooves or trenches, which may provide one or more of the following: (1) high fill factor due to the absence of readout circuits on the device surface, (2) low crosstalk due to the introduction of the inverted V-shape isolation trenches, or (3) high quantum efficiency due to light reflection on the slanted sidewalls of the inverted V-grooves.

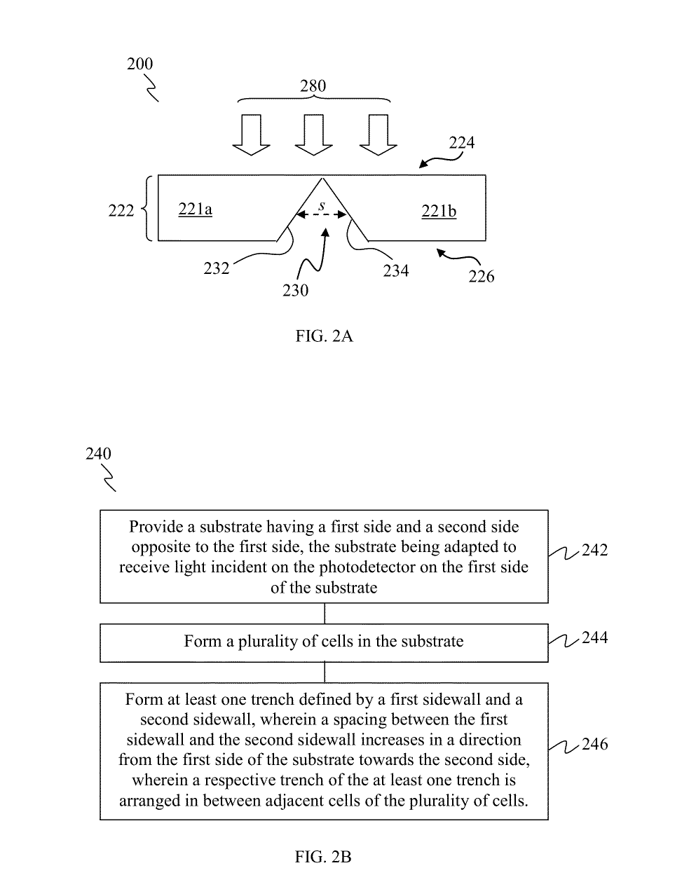

FIG. 2A shows a schematic cross-sectional view of a photodetector 200, according to various embodiments. The photodetector 200 includes a substrate 222 having a first side 224 and a second side 226 opposite to the first side 224, the substrate 222 being adapted to receive light 280 incident on the photodetector 200 on the first side 224 of the substrate 222, a plurality of cells (e.g. as represented by 221a, 221b for two cells) formed in the substrate 222, and at least one trench 230 defined by a first sidewall 232 and a second sidewall 234, wherein a spacing, s, between the first sidewall 232 and the second sidewall 234 increases in a direction from the first side 224 of the substrate 222 towards the second side 226, wherein a respective trench 230 of the at least one trench 230 is arranged in between adjacent cells 221a, 221b of the plurality of cells 221a, 221b.

In other words, the photodetector 200 may include a substrate 222 and a plurality of cells (e.g. photocells) 221a, 221b formed in the substrate 222. The substrate 222 may have opposite sides (first side 224 and second side 226). The first side 224 may be a side from which the light 280 incident on the photodetector 200 may be received or collected by the cells 221a, 221b. This may mean that the first side 224 may be a light incident side or a light sensitive side. In this way, light 280 incident on the photodetector 200 may enter the substrate 222 from the first side 224 and traverse within the substrate 222 towards the second side 226.

At least one trench (or groove) 230 may be defined in the substrate 222, at least partially through the substrate 222. Each trench 230 may be defined by a first sidewall 232 and a second sidewall 234 where the first sidewall 232 and the second sidewall 234 may diverge in a direction away from the first side 224 of the substrate 222 towards the second side 226. In this way, an opening of the at least one trench 230 may be defined proximate to the second side 226 of the substrate 222, away from the first side 224 where the light 280 may be incident. Therefore, a high fill factor (FF), which may be as high as 100%, may be maintained while crosstalk between adjacent cells 221a, 221b may be reduced, as the surface area for light detection on the first side 224 may be maintained as large as possible.

At least one of the first sidewall 232 or the second sidewall 234 may be an inclined or slanted sidewall. This may mean that the first sidewall 232 and/or the second sidewall 234 may be arranged inclined relative to a surface of the substrate on the first side 224 and also inclined to an axis defined at least substantially perpendicular to the surface of the substrate 222 on the first side 224.

In the context of various embodiments, at least one of the first sidewall 232 or a second sidewall 234 may act as a light director or reflector to reflect the light 280 incident on the photodetector 200 into a cell (e.g. 221a), for example towards a central portion of said cell.

In various embodiments, the first sidewall 232 and the second sidewall 234 may be arranged on opposite sides of an axis defined at least substantially perpendicular to the surface of the substrate 222 on the first side 224.

In the photodetector 200, a respective trench 230 of the at least one trench 230 may be arranged in between neighbouring cells 221a, 221b of the plurality of cells 221a, 221b. This may mean that a respective trench 230 may be defined at a boundary area between adjacent cells 221a, 221b.

In the context of various embodiments, each respective trench 230 may act as a separation or isolation structure between two adjacent cells 221a, 221b. Each respective trench 230 may provide optical isolation between the adjacent cells 221a, 221b, which may therefore minimize optical coupling between the adjacent cells 221a, 221b. Therefore, each respective trench 230 may act as an optical barrier. Accordingly, each respective trench 230 may provide isolation of a cell (e.g. 221a) from its neighbouring cells (e.g. 221b) and from any other cells of the photodetector 200.

In the context of various embodiments, each cell 221a, 221b may be an individual or separate cell. Each cell 221a, 221b may be independent from each other, for example, each cell 221a, 221b may be used independently for detecting the incident light 280 or photons. This may mean that a cell 221a, 221b may provide a measurement of the incident light 280 or photons impinging on the respective cells 221a, 221b independently from the other cells 221a, 221b. In the context of various embodiments, each cell 221a, 221b may correspond to a respective pixel.

In the context of various embodiments, each cell 221a, 221b may include a diode (e.g. a photodiode, e.g. an avalanche photodiode (APD)).

In various embodiments, the first sidewall 232 may be arranged inclined to a surface of the substrate 222 on the first side 224. The first sidewall 232 may be inclined at an angle, φ, of between about 20° and about 80°, for example, between about 20° and about 50°, between about 50° and about 80°, or between about 40° and about 60°, e.g. at about 54.74°. In various embodiments, the second sidewall 234 may be arranged inclined to the surface of the substrate 222 on the first side 224. The second sidewall 234 may be inclined at an angle, α, of between about 20° and about 80°, for example, between about 20° and about 50°, between about 50° and about 80°, or between about 40° and about 60°, e.g. at about 54.74°.

In various embodiments where the substrate 222 may include crystalline silicon (Si), the at least one trench 230 may be aligned along the <110> direction such that the (111) planes of the Si material may be revealed during anisotropic etching of the crystalline Si. As a result, an angle of about 54.74° may be achieved between the (100) crystal plane and the (111) crystal plane of the crystalline Si.

In various embodiments, the at least one trench 230 may be formed through the entire thickness of the substrate 222.

In various embodiments, the first sidewall 232 and the second sidewall 234 may converge to a contact line. In various embodiments, the first sidewall 232 and the second sidewall 234 may meet each other at a contact line or interface line. For example, the contact line may form a base of the at least one trench 230 proximate to the first side 224.

In various embodiments, respective ends of the first sidewall 232 and the second sidewall 234 may contact each other, for example meet at a point.

In the context of various embodiments, the first sidewall 232 and the second sidewall 234 may be arranged inclined to the surface of the substrate 222 on the first side 224. With the spacing, s, between the first sidewall 232 and the second sidewall 234 increasing in the direction from the first side 224 towards the second side 226, the at least one trench 230 may resemble an inverted V shape, as shown in FIG. 2A when light 280 is incident on a top side of the photodetector 200.

In the context of various embodiments, each cell 221a, 221b of the plurality of cells 221a, 221b may include a first region of a first conductivity type adjacent to the front side 224. The first region may be formed in the substrate 222. The first region may be an active region of the cell 221, 221b which may receive the light 280 incident on the photodetector 200.

In various embodiments, the respective first regions of the plurality of cells 221a, 221b may form a continuous region. This may mean that a common first region may be provided in the photodetector 200, which may function as a common electrode for the plurality of cells 221, 221b. The first region may serve as an anode.

In the context of various embodiments, the first region of each cell 221a, 221b may be doped with dopants of the first conductivity type at a concentration of between about 10¹⁸/cm³ and about 10²¹/cm³, for example between about 10¹⁸/cm³ and about 10²⁰/cm³, between about 10¹⁸/cm³ and about 10¹⁹/cm³, or between about 10¹⁹/cm³ and about 10²¹/cm³.

In the context of various embodiments, each cell 221a, 221b of the plurality of cells 221a, 221b may further include a second region of a second conductivity type adjacent to the second side 226. Accordingly, the first region and the second region of each cell 221a, 221b may be of opposite conductivity types. Also, the first region and the second region of each cell 221a, 221b may be provided towards opposite sides of the substrate 222. The second region of each cell 221a, 221b may be formed in the substrate 222. The second region of each cell 221a, 221b may serve as a cathode for each cell 221a, 221b.

In the context of various embodiments, the second region of each cell 221a, 221b may be doped with dopants of the second conductivity at a concentration of between about 10¹⁸/cm³ and about 10²¹/cm³, for example between about 10¹⁸/cm³ and about 10²⁰/cm³, between about 10¹⁸/cm³ and about 10¹⁹/cm³, or between about 10¹⁹/cm³ and about 10²¹/cm³.

In the context of various embodiments, the first region and the second region of a respective cell 221a, 221b may define a respective diode (e.g. an APD). The first region and the second region may serve as an anode and a cathode, respectively, for the diode.

In various embodiments, each cell 221a, 221b may further include an intermediate region of the first conductivity type between the first region and the second region. The intermediate region may act as a charge layer. The intermediate region may be spaced apart from at least one of the first region or the second region. The intermediate region may be arranged equidistant from each of the first region and the second region. However, it should be appreciated that the intermediate region may be arranged at different respective distances from each of the first region and the second region, i.e. not equidistant. The intermediate region may include dopants of the first conductivity type at a concentration equal to or lower than a concentration of dopants of the first conductivity type in the first region. In the context of various embodiments, the intermediate region may be doped with dopants of the first conductivity type at a concentration of between about 10¹⁴/cm³ and about 10¹⁸/cm³, for example between about 10¹⁴/cm³ and about 10¹⁶/cm³, between about 10¹⁶/cm³ and about 10¹⁸/cm³, or between about 10¹⁵/cm³ and about 10¹⁷/cm³.

In various embodiments, each cell 221a, 221b may further include an intermediate region of the second conductivity type between the first region and the second region. The intermediate region may at least substantially contact the first region. The intermediate region may extend into the substrate 222 towards the second region. The intermediate region may include dopants of the second conductivity type at a concentration equal to or lower than a concentration of dopants of the second conductivity type in the second region. In the context of various embodiments, the intermediate region may be doped with dopants of the second conductivity type at a concentration of between about 10¹⁴/cm³ and about 10¹⁸/cm³, for example between about 10¹⁴/cm³ and about 10¹⁶/cm³, between about 10¹⁶/cm³ and about 10¹⁸/cm³, or between about 10¹⁵/cm³ and about 10¹⁷/cm³.

In various embodiments, each cell 221a, 221b may further include a resistor (e.g. a polysilicon resistor). The resistors may be arranged adjacent to the second side 226 of the substrate 222. Each resistor may be an integrated resistor. A respective resistor may be electrically coupled to the diode of the corresponding cell 221a, 221b. For example, a respective resistor may be electrically coupled to the second region of the corresponding cell 221a, 221b, for example via a respective metal wire.

In various embodiments, the photodetector 200 may further include an insulating material (e.g. an oxide) in between the first sidewall 232 and the second sidewall 234 of the at least one trench 230.

In various embodiments, the photodetector 200 may further include at least one electrical interconnection coupled to the plurality of cells 221a, 221b. The at least one electrical interconnection may allow electrical communication between adjacent cells 221a, 221b and/or among the plurality of cells 221a, 221b. The at least one electrical interconnection may be arranged adjacent to the second side 226 of the substrate 222. The at least one electrical interconnection may include a metal wire.

In various embodiments, the photodetector 200 may further include a readout circuit electrically coupled to the plurality of cells 221a, 221b. The readout circuit may be arranged adjacent to the second side 226 of the substrate 222. The readout circuit may provide a signal indicative of the light detected by each respective cell 221a, 221b.

In various embodiments, the photodetector 200 may further include a support carrier coupled to the substrate 222. The support carrier may be bonded to the substrate 222.

In various embodiments, the support carrier may be coupled to the second side 226 of the substrate 222. The support carrier may include a silicon wafer or substrate.

In various embodiments, the support carrier may be at least substantially transparent. The transparent support carrier may be coupled (e.g. bonded) to the first side 224 of the substrate 222.

In the context of various embodiments, the photodetector 200 may be silicon-based.

In the context of various embodiments, the substrate 222 may be or may include silicon (Si). The substrate 222 may include one or more silicon (Si) epitaxial layer(s).

In the context of various embodiments, the first conductivity type may be a p-type conductivity type, and the second conductivity type may be an n-type conductivity type.

In the context of various embodiments, the first conductivity type may be an n-type conductivity type, and the second conductivity type may be a p-type conductivity type.

In the context of various embodiments, the photodetector 200 may be employed for visible light detection, meaning that the photodetector 200 may be responsive to visible light wavelengths.

In the context of various embodiments, the photodetector 200 may be a semiconductor photodetector (e.g. a silicon (Si) photodetector), for example a semiconductor photomultiplier device, such as a silicon photomultiplier device (SiPM).

FIG. 2B shows a flow chart 240 illustrating a method for forming a photodetector, according to various embodiments.

At 242, a substrate having a first side and a second side opposite to the first side is provided, the substrate being adapted to receive light incident on the photodetector on the first side of the substrate.

At 244, a plurality of cells are formed in the substrate.

At 246, at least one trench defined by a first sidewall and a second sidewall is formed, wherein a spacing between the first sidewall and the second sidewall increases in a direction from the first side of the substrate towards the second side, wherein a respective trench of the at least one trench is arranged in between adjacent cells of the plurality of cells.

Various embodiments may provide a photodetector (e.g. a Si photodetector) having inverted V-grooves or trenches between adjacent cells of the photodetector. The inverted V-grooves may be formed via anisotropic wet etching. In forming the photodetector, the device wafer including the cells may be bonded to a support carrier to achieve a final structure of the photodetector.

The inverted V-grooves may serve as both isolation trenches and reflection mirrors. As isolation trenches, the inverted V-grooves may serve as barriers to photons and photocarriers. In this way, the inverted V-grooves may serve as optical barriers between adjacent cells of the photodetector to eliminate or at least minimise optical coupling between adjacent cells when light or incident photons are received by a cell so as to reduce crosstalk with neighbouring cells.

As reflection mirrors, the inverted V-grooves may redirect an incident light received by a cell towards a central portion of the cell so as to increase light detection efficiency, and therefore the quantum efficiency of the photodetector. In this way, the incident photons may be reflected by means of the inverted V-grooves from the edge of the cell to the center of the cell. At the center region of the cell, photons may be more easily detected because an electric field in a vicinity of this center region is much stronger than that at the edge of the cell. Therefore, the inverted V-grooves may help to improve the efficiency at the edges of the cells, in addition to the photon detection efficiency which is maintained high at the center of the photodiode cell.

Accordingly, simultaneous improvements on the crosstalk property and the photon detection efficiency (PDE) of the photodetector may be achieved, without a compromise between each other. In this way, no trade-offs may be needed between the crosstalk and the photon detection efficiency of the photodetector. Further, elimination of metal wires and readout circuits in the array area of the photodetector of various embodiments may be achieved. This may increase the fill factor (FF) of the photodetector, thereby increasing the photon detection efficiency of the photodetector.

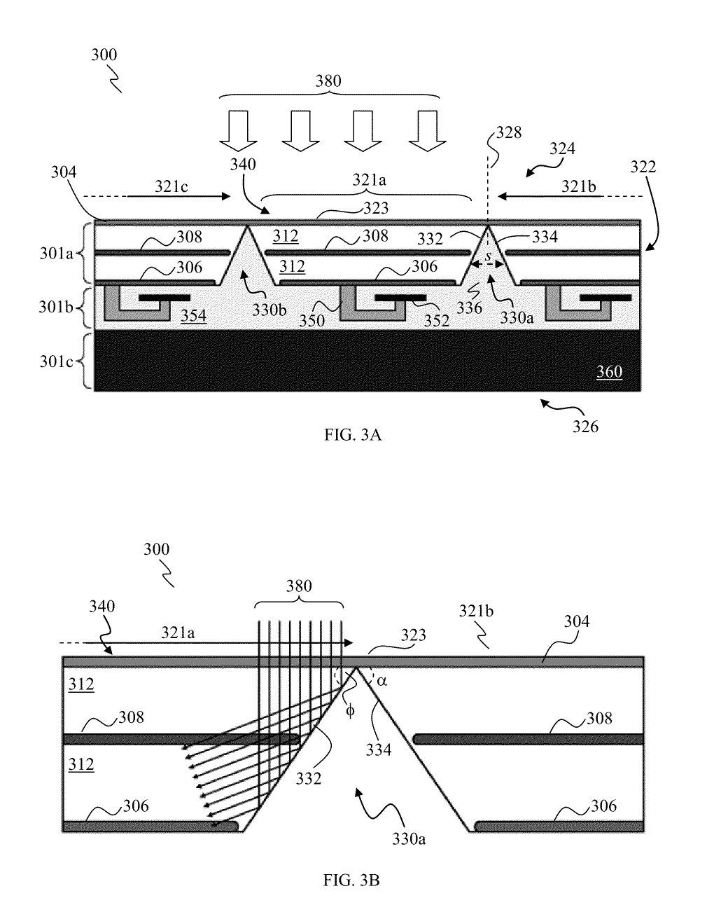

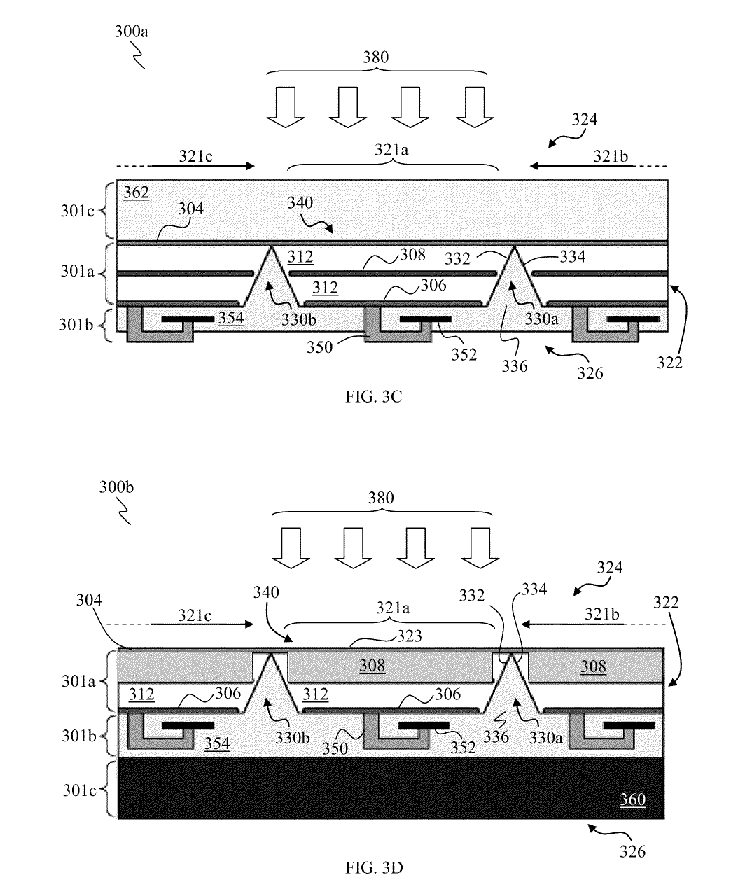

FIG. 3A shows a schematic partial cross-sectional view of a photodetector 300, according to various embodiments, illustrating a photodetector array structure having a SACM (Separation of Absorption, Charge, Multiplication) structure. The photodetector 300 may have a plurality of cells (e.g. photocells), for example two, three, four, five or any higher number of cells. However, for illustration purposes, the photodetector 300 is shown with a cell 321a and parts of adjacent cells 321b, 321c. The photodetector 300 may be formed using a silicon (Si) substrate 322, meaning that the photodetector 300 may be a silicon (Si) photodetector.

As may be seen in FIG. 3A, the photodetector 300 may have three layers or parts. The first part 301a may include a detector or diode array where a plurality of photodiodes may be formed separately. The diode array may be formed in the Si substrate 322. As a non-limiting example, a diode may be provided in a respective cell 321a, 321b, 321c, e.g. diode 340 is provided in the cell 321a. The second part 301b may be used for providing one or more electrical interconnections between different photodiodes, including metal wires (e.g. 350), integrated resistors (e.g. 352) and so on. The detected signal(s) from each diode may be obtained from one or more readout circuits (not shown) provided in the second part 301b. The third part 301c may include a support carrier 360 serving as a mechanical support to the device layers (e.g. the first part 301a and the second part 301b) of the photodetector 300.

Using the cell 321a as a non-limiting example, the cell 321a includes a diode (e.g. an avalanche photo diode (APD)) 340 formed in the substrate 322. The diode 340 may include a doped region (e.g. a first region) 304 of a first conductivity type, for example a highly doped p+ region, adjacent to a front side 324 of the substrate 322, and another doped region (e.g. a second region) 306 of a second conductivity type, for example a highly doped n+ region. The first region 304 may define an active region, and may include a detection window for the cell 321a, through which light or photons (as represented by the arrows 380) incident on the photodetector 300 may be received by the diode 340, and therefore also received by the cell 321a. The first region 304 may serve as an electrode (e.g. as an upper electrode) for the diode 340, while the second region 306 may serve as another electrode (e.g. as a lower electrode) for the diode 340. In various embodiments, the first region 304 may be a common region shared by the plurality of cells including cells 321a, 321b, 321c. In this way, the first region 304 may act as a common contact region (e.g. as an anode) for all cells in the photodetector 300. However, it should be appreciated that respective separate first regions 304 may be provided for respective cells 321a, 321b, 321c. Each cell 321a, 321b, 321c of the plurality of cells may be a separate or individual cell. Each cell 321a, 321b, 321c may provide a measurement indicative of the light 380 incident on the cell, independently from the other cells.

The diode 340 may include a further doped region 308 of a first conductivity type, for example a lightly doped p− region, formed within or embedded in the substrate 322 as an intermediate region between the doped regions 304, 306. The intermediate region 308 may be formed at least substantially overlapping with the doped regions 304, 306. The intermediate region 308 may be arranged beneath the first region 304 and spaced apart from the first region 304. The intermediate region 308 may be spaced apart from the second region 306. Further, the intermediate region 308 may be formed equidistant from the first region 304 and the second region 306. There may be intrinsic or undoped regions 312 in between the first region 304 and the intermediate region 308 and between the intermediate region 308 and the second region 306. In further embodiments, it should be appreciated that the intermediate region 308 may not be formed equidistant from each of the first region 304 and the second region 306.

The cell 321a may further include a resistor 352 electrically coupled in series with the diode 340. The resistor 352 may be electrically coupled to the diode 340 via a metal wire 350, for example electrically coupled to the second region 306. The resistor 352 may be integrated in the photodetector 300. The resistor 352 may be formed embedded in a passivation or insulation layer (e.g. an oxide layer) 354. The metal wire 350 may also be embedded in the insulation layer 354.

It should be appreciated that similar or like features in the cells 321b, 321c may be as described in the context of the cell 321a.

As shown in FIG. 3A, inverted V-grooves or trenches may be provided in the photodetector 300. For example, a trench 330a may be provided between the adjacent cells 321a, 321b, while another trench 330b may be provided between the adjacent cells 321a, 321c. This may mean that the trench 330a may be formed at a boundary area of each of the adjacent cells 321a, 321b for separating the adjacent cells 321a, 321b, while the trench 330b may be formed at a boundary area of each of the adjacent cells 321a, 321c for separating the adjacent cells 321a, 321c. Therefore, the respective trenches 330a, 330b may act as isolation trenches between respective adjacent or neighbouring cells.

Using the trench 330a as a non-limiting example, the trench 330a may be defined by a first sidewall 332 and a second sidewall 334. Each of the first sidewall 332 and the second sidewall 334 may be a slanted or inclined sidewall. This may mean that each of the first sidewall 332 and the second sidewall 334 may be formed inclined to a surface 323 of the substrate 322 and also inclined to an axis (as represented by 328) defined at least substantially perpendicular to the surface 323. The first sidewall 332 and the second sidewall 334 may be arranged relative to each other in a way such that a spacing, s, between the first sidewall 332 and the second sidewall 334 may increase in a direction from the first side 324 towards the second side 326 of the substrate 322. This may mean that the first sidewall 332 and the second sidewall 334 may converge towards each other proximate to the first side 324 and may diverge away from each other proximate to the second side 326, thereby defining an opening 336. The respective ends or tips of the first sidewall 332 and the second sidewall 334 may converge and may come into contact with each other (e.g. meet at a point) proximate to the first side 324 of the substrate 322. The material of the insulation layer 354 may fill the space between the first sidewall 332 and the second sidewall 334. It should be appreciated that the trench 330b may be similarly as described in the context of the trench 330a. Accordingly, as may be observed in FIG. 3A, with the first side 324 of the substrate 322, where light 380 is incident, as the top side of the photodetector 300, each of the trenches 330a, 330b may resemble an inverted V shape.

In operation, the top surface 323 of the device or photodetector 300 may be adopted for collection of the incident light 380. This may mean that the first side 324 may be a light incident side or a light sensitive side of the photodetector 300. The light 380 may then travel in a direction from the first side 324 into the substrate 322 towards the second side 326, thereby interacting with the diodes in the photodetector 300, including the diode 340. As the readout circuit(s) (not shown) may be located on the other side of the diodes (e.g. 340), towards the second side 326, the fill factor (FF) of the photodetector 300 may be greatly increased. This is because a substantial amount of the surface 323, if not the entire surface 323, and therefore also the first region 304 may be exposed and may therefore be used to receive the incident light 380.

Further, the fill factor increase may also result from the inverted V-shape isolation trenches 330a, 330b between adjacent cells 321a, 321b, 321c. As may be seen in FIG. 3A, the top surface 323 of the photodetector 300 may not be consumed by any portion of the isolation trenches 330a, 330b. Rather, the respective openings 336 of the trenches 330a, 330b are arranged on the other side of the diodes (e.g. 340) towards the second side 326, which is less sensitive to the incident light 380. Therefore, a very limited or minimal reduction of the effective fill factor may be caused by the isolation trenches 330a, 330b. Further, the crosstalk between adjacent cells 321a, 321b, 321c may be greatly reduced as a result of the presence of the trenches 330a, 330b which may minimize optical coupling between adjacent cells 321a, 321b, 321c.

Furthermore, each of the inverted V-grooves 330a, 330b introduces slanted interfaces or sidewalls 332, 334 within the photodetector 300. The inclined sidewalls 332, 334 may serve as reflection mirrors for the incident light 380. Such a reflection effect may be attributed, at least partially, to the high refractive index of silicon (Si), when used as the material for the photodetector 300. FIG. 3B shows a schematic partial cross-sectional view of the photodetector 300 of the embodiment of FIG. 3A, when light 380 is incident on the photodetector 300. For illustration purposes, only the first part 301a and portions of the adjacent cells 321a, 321b are shown in FIG. 3B.

As shown in FIG. 3B, the first sidewall 332 of the trench 330a may be arranged inclined at an angle, φ, to the surface 323 of the substrate 322, while the second sidewall 334 may be arranged inclined at an angle, a, to the surface 323 of the substrate 322. As the light 380 is incident on the photodetector 300, at least a portion of the light 380 may impinge on the first sidewall 332 of the trench 330a and total internal reflection of the incident light 380 may occur at the slanted sidewall 332 of the inverted V-groove 330a. As illustrated in FIG. 3B, the light 380 impinging on the photodetector 300 in a vicinity of the trench area may be reflected to the adjacent diode 340 of the cell 321a for more efficient detection of the light 380. Thus, the quantum efficiency of the device or photodetector 300 may be further enhanced.

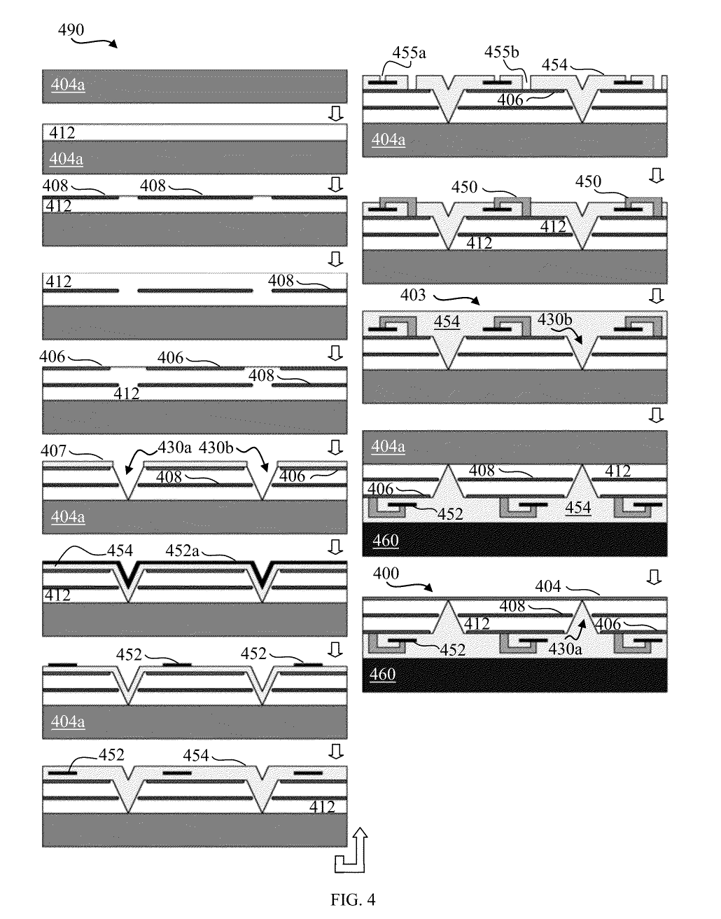

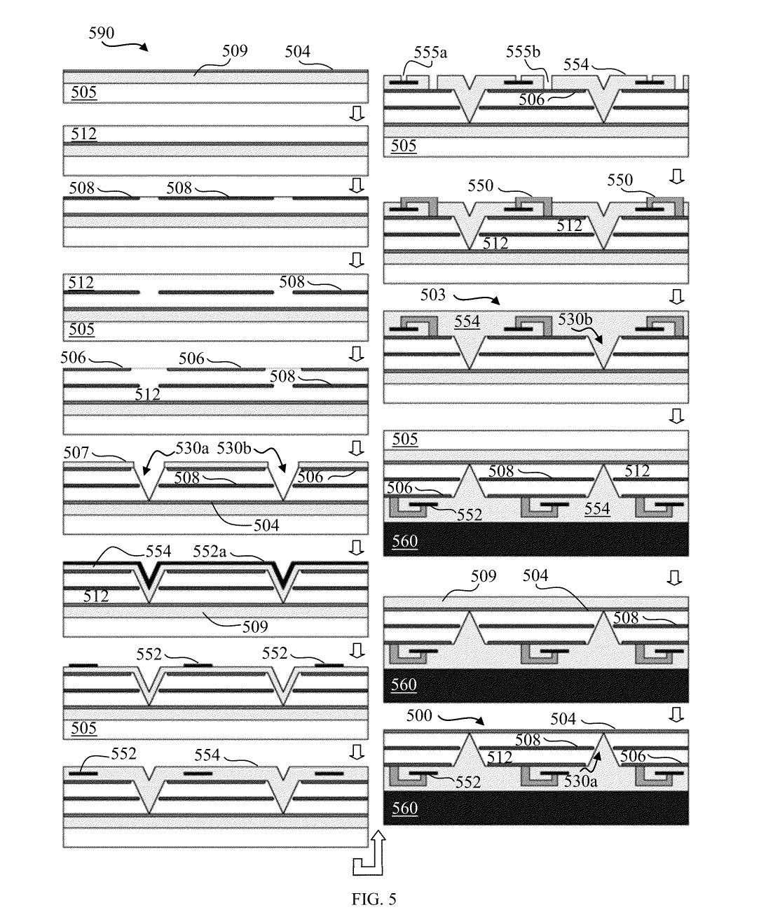

As non-limiting examples, the device structure as shown in FIG. 3A may be realized by standard silicon (Si) processing technology in the semiconductor industry. First, the diodes 340 and their readout circuits may be fabricated on (100) Si wafers. For example, the diodes may be realized by Si epitaxial growth and ion implantation processes. After that, anisotropic wet etching of the Si material may be carried out to form the inverted V-grooves 330a, 330b. When the Si wafer is immersed into alkaline solutions, the etch rate of the (100) planes is much higher than that of the (111) planes for crystalline Si. Thus, if the V-grooves 330a, 330b are aligned along the <110> direction, the (111) planes of the Si material may be easily revealed during anisotropic etching. Accordingly, inverted V-grooves 330a, 330b with very smooth sidewalls 332, 334 may be achieved. The angle between the (100) plane and the (111) plane may be about 54.74° (degree). Referring to FIG. 3B as an example, the surface 323 may correspond to the (100) plane, while the sidewalls 332, 334 may correspond to the (111) planes such that each of the angles φ and α may be about 54.74°, although there may be a slight variation in the angles φ and α due to less than ideal anisotropic etching. It should be appreciated that the inverted V-grooves 330a, 330b may be formed by other methods. Further, V-grooves of other angles may also be formed, which may lead to improved performances of the corresponding photodetectors. After the formation of the inverted V-grooves 330a, 330b, the device may be covered with dielectric materials and the surface may be polished flat. Then, the device wafer may be flipped upside down and be bonded with a supporting Si wafer as a support carrier. Finally, the substrate of the device wafer may undergo a backside etching and polishing process. A photodetector having a structure as shown in FIG. 3A may thus be achieved. Examples of a detailed fabrication process flow for forming the photodetector 300 will be described later with reference to FIGS. 4 and 5.

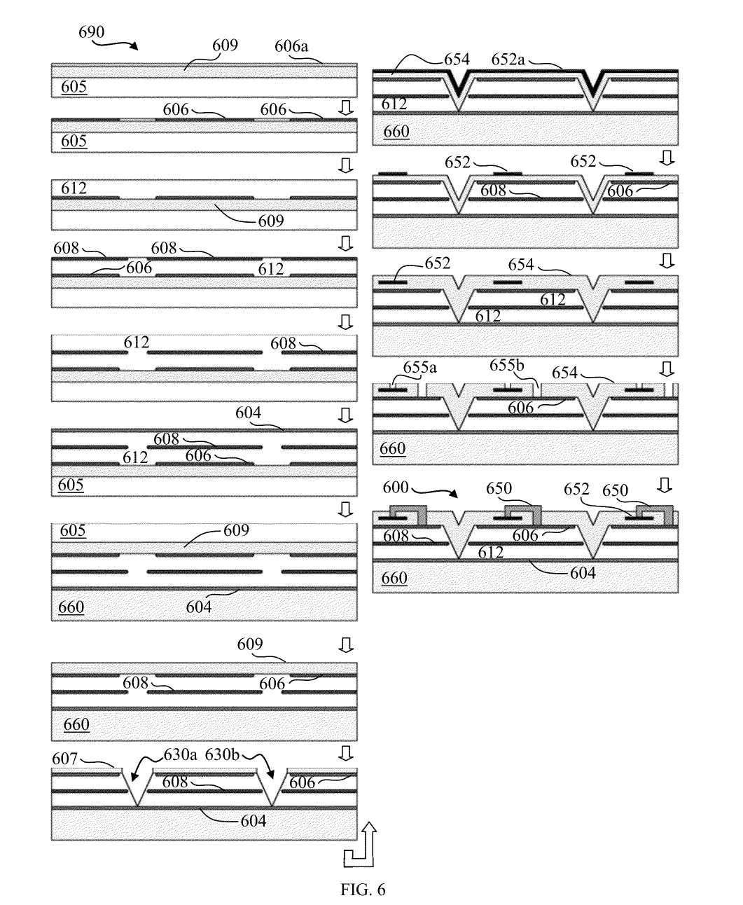

FIG. 3C shows a schematic partial cross-sectional view of a photodetector 300a, according to various embodiments. The photodetector 300a may have a similar structure as the photodetector 300 (FIG. 3A) and may be as described in the context of the photodetector 300, except that the third part 301c of the photodetector 300a may include a support carrier 362 coupled to the front side 324 of the substrate 322, for example by bonding. The support carrier 362 may be a transparent substrate. In operation, the incident light 380 may pass through the at least substantially transparent support carrier 362 and reach the diodes 340 on the other side of the support carrier 362. The photodetector 300a may also benefit from the inverted V-grooves 330a, 330b employed, resulting in low crosstalk and high photon detection efficiency. An example of a detailed fabrication process flow for forming the photodetector 300a will be described later with reference to FIG. 6.

While the diodes 340 illustrated in FIGS. 3A to 3C have a SACM (separate absorption, charge, and multiplication) structure, where the intermediate regions 308, serving as charge layers, may be either p− type or n− type, it should be appreciated that the photodetector structure of various embodiments is not so limited. Any other diode configurations, such as a reach-through structure, may also be incorporated in the photodetectors of various embodiments, as illustrated in FIG. 3D for a photodetector 300b.

The reach-through structure may be similar to that of the SACM structure of FIGS. 3A to 3C except that the intermediate region 308 of the reach-through structure may be of a conductivity type opposite to that of the first region 304. For example, the intermediate region 308 may be a lightly doped n− region. The intermediate region 308 may be formed adjacent and in contact with the first region 304. The intermediate region 308 may extend into the substrate 322 towards the second region 306.

It should be appreciated that for the photodetectors 300, 300a, 300b, the doping types of the first region 304, the second region 306 and the intermediate region 308 may be opposite to those described above.

FIG. 4 shows, as cross-sectional views, various processing stages of a method 490 for forming a photodetector, according to various embodiments. FIG. 4 illustrates a fabrication process flow for forming an avalanche photodiode (APD) array based on a silicon (Si) wafer (e.g. a p+ Si substrate). While FIG. 4 shows the process flow for forming three cells, with three diodes, of a photodetector, it should be appreciated that a similar process flow may be used to form any number of cells for a photodetector.

A highly doped Si substrate, such as a p+ substrate 404a, may first be provided. Si epitaxial growth may then be performed to deposit a Si epitaxial layer 412 on the p+ substrate 404a. By means of lithography and doping, a plurality of intermediate regions 408, as the charge layers, may then be defined in the Si epitaxial layer 412. The intermediate regions 408 may be lightly doped p− regions. Further Si epitaxial growth may then be performed to deposit another Si epitaxial layer over the intermediate regions 408. For illustration purpose, the Si epitaxial layers are collectively indicated as 412. Subsequently, by means of lithography and doping, a plurality of second regions 406 may be defined in the Si epitaxial layer 412. The second regions 406 may be highly doped n+ regions. The respective second regions 406 may act as cathodes for the respective diodes.

Using lithography and etching, a hard mask (e.g. silicon oxide (SiO₂) or silicon nitride (Si₃N₄)) 407 may be deposited and patterned, by means of a resist (not shown), to expose areas in between the second regions 406 and areas in between the intermediate regions 408 where trenches are to be formed. The resist may then be removed. Anisotropic wet etching may then be employed to form V-grooves 430a, 430b via the patterned hard mask 407. The hard mask 407 may then be removed.

An oxide layer 454 may then be deposited over the Si epitaxial layer 412 and at least partially within the V-grooves 430a, 430b, followed by deposition of a polysilicon (poly-Si) layer 452a. By means of doping and dry etching, a plurality of resistors 452 may then be defined from the poly-Si layer 452a. Further oxide deposition may be performed such that the resistors 452 may be embedded within the oxide layer 454.

Subsequently, using lithography and dry etching, a plurality of contact vias may be defined. For example, contact vias 455a may be formed to the resistors 452, while contact vias 455b may be formed to the second regions 406. By means of metalization, lithography and metal etching, a plurality of metal wires 450 may be defined. Each metal wire 450 may electrically couple a resistor 452 and an associated second region 406. Other electrical interconnections, for example for electrical communication between cells, may also be defined. An oxidation process may be performed to deposit an oxide layer over the metal wires 450, followed by a planarization process (e.g. chemical mechanical polishing (CMP)). As a result, the resistors 452 and the metal wires 450 may be embedded in an insulating oxide layer 454. Accordingly, a device wafer 403 may be obtained.

The device wafer 403 may then be flipped and bonding of the device wafer 403 with a support wafer (or support carrier) 460 may be carried out. Back-side grinding and polishing may then be carried out to thin down the device wafer 403. As a result, a continuous first region 404 for the diodes may be provided by thinning the p+ substrate 404a. The first region 404 may act as an anode for the diodes. Accordingly, a photodetector 400 may be formed.

As described above with reference to FIG. 4, the device layer may be achieved using a highly-doped Si wafer 404a. However, in the last step of the process 490, there may be challenges to accurately control the thickness and the uniformity of the first region 404 achieved from thinning-down of the Si wafer 404a. In order to address the above-mentioned issues, the device layer may be fabricated on a silicon-on-insulator (SOI) wafer, as will be described below with reference to FIG. 5. The buried oxide (BOX) layer of the SOI wafer may serve as an etch stop layer during the process of backside etching of the Si base substrate of the SOI wafer. Thus, a greater fabrication tolerance may be achieved.

FIG. 5 shows, as cross-sectional views, various processing stages of a method 590 for forming a photodetector, according to various embodiments. FIG. 5 illustrates a fabrication process flow for forming an avalanche photodiode (APD) array based on a SOI wafer. While FIG. 5 shows the process flow for forming three cells, with three diodes, of a photodetector, it should be appreciated that a similar process flow may be used to form any number of cells for a photodetector.

A SOI wafer may first be provided, where the SOI wafer includes a silicon (Si) base substrate 505, a buried oxide (BOX) layer 509 and a highly doped top Si layer 504. Si epitaxial growth may then be performed to deposit a Si epitaxial layer 512 on the SOI wafer.

Subsequently, the respective processes for defining a plurality of intermediate regions 508 as the charge layers, further Si epitaxial growth, defining a plurality of second regions 506 as cathodes for the respective diodes, deposition and patterning of a hard mask 507, formation of V-grooves 530a, 530b, deposition of an oxide layer 554, deposition of a polysilicon layer 552a, defining a plurality of resistors 552, further oxide deposition, defining a plurality of contact vias 555a, 555b, defining a plurality of metal wires 550 and other electrical interconnections, and a subsequent oxidation process followed by a planarization process (e.g. CMP) may be carried out as described in the context of forming like features or elements for the photodetector 400 (FIG. 4). After the above-mentioned processes, a device wafer 503 may be obtained.

The device wafer 503 may then be flipped and bonding of the device wafer 503 with a support wafer (or support carrier) 560 may be carried out. Back-side grinding and/or Si etching may then be carried out to thin down the SOI wafer, with the BOX layer 509 serving as an etch-stop layer. Back-side polishing may be carried out. Subsequently, the BOX layer 509 may be removed, leaving the Si layer 504 of the SOI wafer as a first region for the diodes. The Si layer 504 may act as an anode for the diodes. Accordingly, a photodetector 500 may be formed.

FIG. 6 shows, as cross-sectional views, various processing stages of a method 690 for forming a photodetector, according to various embodiments. FIG. 6 illustrates a fabrication process flow for forming an avalanche photodiode (APD) array with a transparent support carrier. While FIG. 6 shows the process flow for forming three cells, with three diodes, of a photodetector, it should be appreciated that a similar process flow may be used to form any number of cells for a photodetector.

A silicon-on-insulator (SOI) wafer may first be provided, where the SOI wafer includes a silicon (Si) base substrate 605, a buried oxide (BOX) layer 609 and a thin top Si layer 606a with high resistivity. By means of lithography and doping, a plurality of second regions 606 may be defined from the top Si layer 606a. The second regions 606 may be highly doped n+ regions. The respective second regions 606 may act as cathodes for the respective diodes to be formed. Si epitaxial growth may then be performed to deposit a Si epitaxial layer 612 over the second regions 606. By means of lithography and doping, a plurality of intermediate regions 608, as the charge layers, may then be defined in the Si epitaxial layer 612. The intermediate regions 608 may be lightly doped p− regions. Further Si epitaxial growth may then be performed to deposit another Si epitaxial layer over the intermediate regions 608. For illustration purpose, the Si epitaxial layers are collectively indicated as 612. By means of lithography and doping, a continuous first region 604 may be defined in the Si epitaxial layer 612. The first region 604 may be a highly doped p+ region. The first region 604 may act as an anode for the diodes.

The SOI wafer may be flipped and bonding of the SOI wafer with a transparent support carrier 660 may be carried out. Back-side grinding and/or Si etching may then be carried out to thin down the SOI wafer, with the BOX layer 609 serving as an etch-stop layer. Back-side polishing may be carried out. Subsequently, the BOX layer 609 may be removed.

Using lithography and etching, a hard mask (e.g. silicon oxide (SiO₂) or silicon nitride (Si₃N₄)) 607 may be deposited and patterned, by means of a resist (not shown), to expose areas in between the second regions 606 and areas in between the intermediate regions 608 where trenches are to be formed. The resist may then be removed. Anisotropic wet etching may then be employed to form V-grooves 630a, 630b via the patterned hard mask 607. The hard mask 607 may then be removed.

An oxide layer 654 may then be deposited over the Si epitaxial layer 612 and at least partially within the V-grooves 630a, 630b, followed by deposition of a polysilicon (poly-Si) layer 652a. By means of doping and dry etching, a plurality of resistors 652 may then be defined from the poly-Si layer 652a. Further oxide deposition may be performed such that the resistors 652 may be embedded within the oxide layer 654.

Subsequently, using lithography and dry etching, a plurality of contact vias may be defined. For example, contact vias 655a may be formed to the resistors 652, while contact vias 655b may be formed to the second regions 606. By means of metalization, lithography and metal etching, a plurality of metal wires 650 may be defined. Each metal wire 650 may electrically couple a resistor 652 and an associated second region 606. Other electrical interconnections, for example for electrical communication between cells, may also be defined. Accordingly, a photodetector 600 may be formed.

The fabrication process 690 is slightly different from the respective processes 490, 590, as the anisotropic wet etching of V-grooves 630a, 630b is processed after wafer bonding with the support carrier 660 and backside polishing.

Simulation and analysis of the photodetectors of various embodiments will now be described by way of the following non-limiting examples. Numerical simulations may be performed to verify the functionality of the photodetectors. A Technology Computer Aided Design (TCAD)-based software was used to simulate the fabrication processes and the device characteristics. As various embodiments relate to the introduction of inverted V-grooves and their possible influence on the quantum efficiency, simulations were focused on the performance evaluation of two neighbouring photodiodes, with the readout circuits eliminated and their associated effects omitted. Four structures were simulated for comparison.

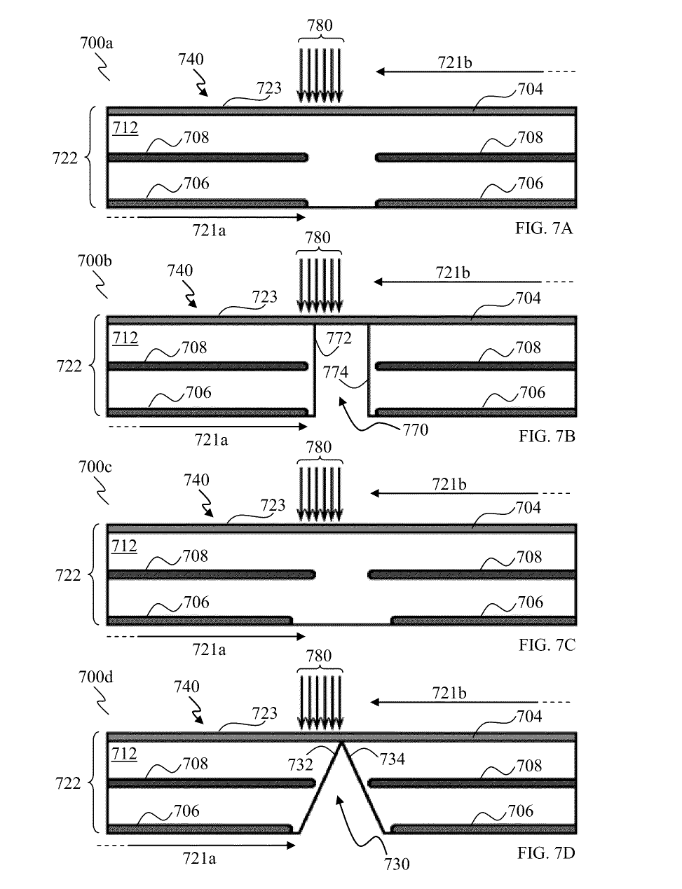

FIGS. 7A to 7D show respective structures 700a (structure A), 700b (structure B), 700c (structure C), 700d (structure D) used for simulation of different photodetectors. Each structure 700a, 700b, 700c, 700d includes adjacent cells 721a, 721b formed in a silicon (Si) substrate 722. The cells 721a, 721b are based on APD diodes with a SACM (separate absorption, charge and multiplication) structure.

The cells 721a, 721b include a first region 704. Each cell 721a, 721b includes a second region 706, and an intermediate region 708 between the first region 704 and the second region 706. The remaining portion of each cell 721a, 721b may be an intrinsic region 712 of the Si substrate 722. The first region 704, the second region 706 and the intermediate region 708 may define a diode, e.g. indicated as diode 740 for the cell 721a. Light 780 may be incident on the first region 704.

The structures 700a, 700b may be similar, except that the structure 700a has no isolation trench between the adjacent cells 721a, 721b, while for the structure 700b, an isolation trench, in the form of an inverted U-trench 770, is defined between the adjacent cells 721a, 721b. The inverted U-trench 770 has two parallel sidewalls 772, 774 that are at least substantially perpendicular to a surface 723 of the Si substrate 722. The inverted U-trench 770 may be achieved by dry etching of Si.

The structures 700c, 700d may be similar, except that the structure 700c has no isolation trench between the adjacent cells 721a, 721b, while for the structure 700d, an isolation trench, in the form of an inverted V-trench 730, is defined between the adjacent cells 721a, 721b. The inverted V-trench 730 has a first sidewall 732 and a second sidewall 734, where both sidewalls 732, 734 are inclined to a surface 723 of the Si substrate 722.

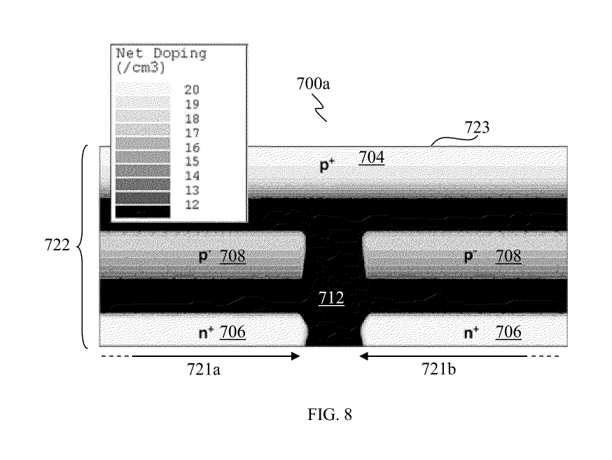

The doping profiles of the structures 700a, 700b, 700c, 700d may be realized by Si epitaxial growth and ion implantation. FIG. 8 shows a doping profile of the structure 700a as one non-limiting example. The doping profile shown in FIG. 8 may be applicable also to the structures 700b, 700c, 700d, where the doping profile along the vertical direction (e.g. the direction from the surface 723 into the substrate 722 towards the second regions 706) may be identical in the structures 700a, 700b, 700c, 700d. The lateral dimension of the doping areas or regions may vary with the dimension of the isolation trenches 730, 770. For ease of comparison, the doping areas in the structure 700a is at least substantially similar to those of the structure 700b. Similarly, the doping areas in the structures 700c, 700d may be at least substantially similar.

The light responses of the structures 700a, 700b, 700c, 700d may be simulated by introducing a vertically incident light beam from the top of the device surface. The location, dimension and light intensity of the beams may be the same for the four different structures 700a, 700b, 700c, 700d. The light wavelength of interest may range from about 300 nm to about 800 nm. The light intensity within the device may be obtained according to the wavelength dependent refractive index and absorption coefficient of Si.

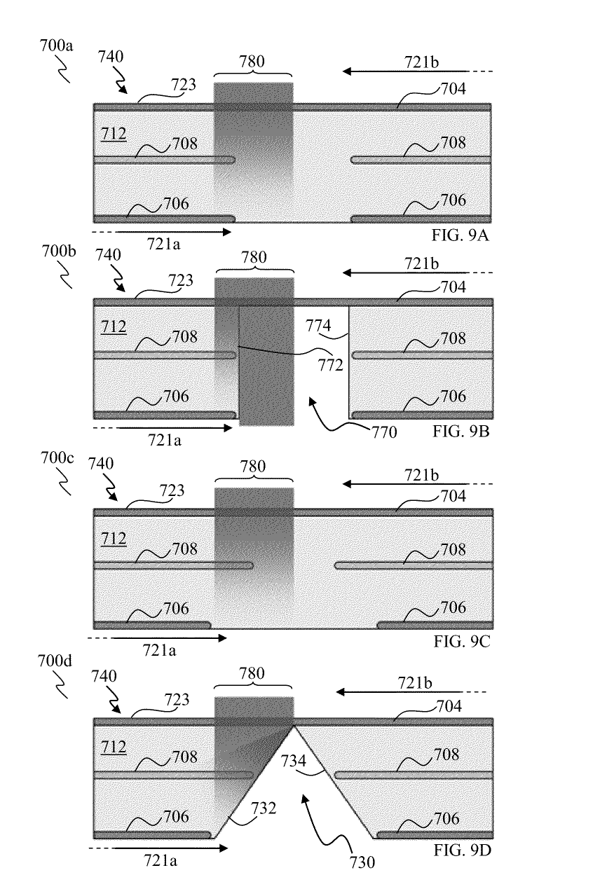

FIGS. 9A to 9D show the simulated light intensity distributions at a predetermined wavelength for the respective structures 700a, 700b, 700c, 700d. A vertical incident light 780 may be launched to the first region 704. In FIGS. 9A to 9D, the light intensity attenuation is due to the absorption of light by silicon.

The crosstalk characteristics of the structures 700a, 700b, 700c, 700d will now be described. As illustrated in FIGS. 7A to 7D and 9A to 9D, a beam of light 780 of different wavelengths may be launched to the boundary areas (e.g. trench areas) between the adjacent cells 721a, 721b of the structures 700a, 700b, 700c, 700d under simulation. The respective responses of the two neighboring diodes of the respective cells 721a, 721b may be obtained separately by evaluation of the photocurrents from them. As the light beam 780 is launched at the edge of the diode of the cell 721a, the diode of the cell 721b should, in an ideal situation, present no response. Thus, a ratio between the photocurrent from the diode of the cell 721b and the photocurrent from the diode of the cell 721a may be defined as crosstalk.

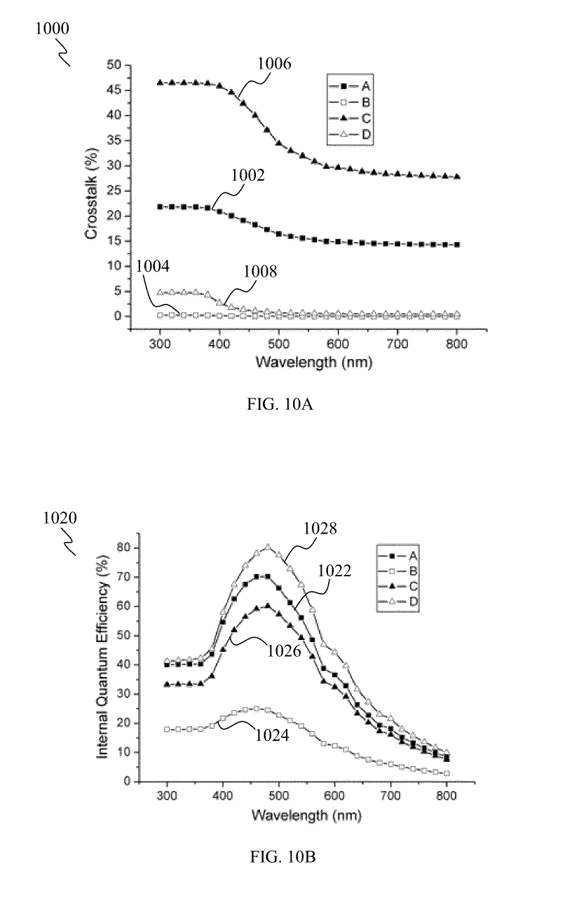

FIG. 10A shows a plot 1000 of crosstalk results for the respective structures 700a, 700b, 700c, 700d, illustrating the crosstalk characteristics of the four structures 700a, 700b, 700c, 700d, as a function of light wavelength. Plot 1000 shows result 1002 corresponding to the structure 700a, result 1004 corresponding to the structure 700b, result 1006 corresponding to the structure 700c, and result 1008 corresponding to the structure 700d.

As may be observed, the structure 700a exhibits a lower crosstalk than the structure 700c, although no isolation trenches were introduced in both structures 700a, 700c. This difference in the crosstalk characteristic may be caused by the different doping areas of the respective structures 700a, 700c as shown in FIGS. 7A, 7C, 9A and 9C. The distance between the two neighbouring charge layers 708 (equivalently also the p− regions 708 of FIG. 8) in the structure 700a is larger than the corresponding distance in the structure 700c. Thus, it may be easier for photons impinging in this area to be collected by the adjacent cells 721a, 721b of the structure 700c.

With the introduction of the isolation trenches in the structures 700b (inverted U-trench 770) and 700d (inverted V-trench 730), the crosstalk of the corresponding devices may be greatly reduced, as shown in FIG. 10A. The crosstalk in the structure 700d may be reduced to about 1.7-10% of that in the structure 700c, while the crosstalk in the structure 700b is only about 0.1-1.1% of that in the structure 700a. The crosstalk of the structure 700d may be slightly higher than that of the structure 700b. This may be attributed to the small isolation gap near the device surface 723 for the inverted V-groove 730, in contrast to the relatively wider gap for the inverted U-groove 770. The smaller the gap is, the easier it may be for photons to pass through the isolation trench and be detected by an adjacent cell.

The photon detection efficiency of the structures 700a, 700b, 700c, 700d will now be described. As shown in FIGS. 7A to 7D, when a beam of light 780 is launched to the edge of the left cell 721a in the structures 700a, 700b, 700c, 700d, the quantum efficiency of each corresponding device may be calculated according to the current response of the photodiode and the incident power of the light 780 at a predetermined or certain wavelength. As the light 780 is only launched at the edge of the left cell 721a, the response detected from the right cell 721b was not included in the quantum efficiency calculation.

FIG. 10B shows a plot 1020 of internal quantum efficiencies, as a function of light wavelength, for the respective structures 700a, 700b, 700c, 700d. Plot 1020 shows result 1022 corresponding to the structure 700a, result 1024 corresponding to the structure 700b, result 1026 corresponding to the structure 700c, and result 1028 corresponding to the structure 700d.

As may be observed, the structure 700a exhibits a higher quantum efficiency than the structure 700c. This difference may be related to their corresponding crosstalk characteristics shown in FIG. 10A. As the crosstalk of the structure 700c is much higher than that of the structure 700a, more light may be coupled to and be detected by the neighboring cell 721b. Thus, the light response of the “correct cell” (the left cell 721a) may be accordingly lower.

With the introduction of the inverted U-groove 770 in the structure 700b, the quantum efficiency of the corresponding device may be decreased drastically, as shown in FIG. 10B. On average, the quantum efficiency of the structure 700b is only about 36.3% of that of the structure 700a. This result is in accordance with the light absorption illustrated in FIG. 9B. As may be seen, a certain amount of light passes through the inverted U-trench 770 without being detected. Thus, while the introduction of inverted U-shaped isolation trenches may reduce crosstalk, the photon detection efficiency may also be reduced.

With the inverted V-groove 730 introduced in the structure 700d, however, a higher quantum efficiency may be observed, in comparison with the corresponding structure 700c without an isolation trench. For all the considered wavelengths, an increase of an average of about 32% may be observed from FIG. 10B. This improvement is in accordance with expectation, as the slanted sidewalls 732, 734 of the inverted V-groove 730 may serve as reflection mirrors to reflect the incident light 780 as shown in FIG. 9D (see also FIG. 3B). Rather than passing through the V-trench 730, the light impinging in this area may be reflected into the center part of the photodiode 740 for more efficient light detection, thereby resulting in an increased detection efficiency.

As described above, various embodiments may provide a photodetector (e.g. a silicon (Si) photodetector array, e.g. a Si photomultiplier device) structure, where inverted V-grooves or trenches are introduced into the photodetector. The inverted V-grooves may serve as isolation trenches to reduce the crosstalk between adjacent cells of the photodetector. Furthermore, the slanted or inclined sidewalls of the V-grooves may also serve as reflection mirrors for more efficient light detection. Light launched to the trench area or region may be reflected by the inclined sidewalls of the V-grooves to the center of the detector cell, and hence may be detected more efficiently. Therefore, the crosstalk property and the photon detection efficiency (PDE) of the photodetector may be improved simultaneously, with no requirement or necessity for consideration of the trade-offs between both parameters. Various embodiments may further allow elimination of readout circuits on the device surface. Accordingly, the photodetector (e.g. a silicon (Si) photodetector array) of various embodiments may provide at least one of high fill factor (FF), increased photon detection efficiency (PDE), or low crosstalk.

Numerical simulation results as described above show that when light is launched to the edge of one photodetector cell, the introduction of an isolation trench may lower the crosstalk of the detector array by at least one order of magnitude. For photodetector arrays with conventional U-trenches, the crosstalk reduction is accompanied by a decrease in the photon detection efficiency. An average decrease of the quantum efficiency as large as 63.7% may be observed. In contrast, for the photodetector arrays of various embodiments with inverted V-grooves, the photon detection efficiency improves together with the crosstalk reduction. On average, an approximate 32% increase in quantum efficiency may be achieved.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A photodetector comprising:
a substrate having a first side and a second side opposite to the first side, the substrate being adapted to receive light incident on the photodetector on the first side of the substrate;
a plurality of cells formed in the substrate; and
at least one trench defined by a first sidewall and a second sidewall, wherein a spacing between the first sidewall and the second sidewall increases in a direction from the first side of the substrate towards the second side,
wherein a respective trench of the at least one trench is arranged in between adjacent cells of the plurality of cells.

2. The photodetector as claimed in claim 1, wherein the first sidewall is arranged inclined to a surface of the substrate on the first side.

3. The photodetector as claimed in claim 2, wherein the first sidewall is inclined at an angle of between about 20° and about 80°.

4. The photodetector as claimed in claim 2, wherein the second sidewall is arranged inclined to the surface of the substrate on the first side.

5. The photodetector as claimed in claim 4, wherein the second sidewall is inclined at an angle of between about 20° and about 80°.

6. The photodetector as claimed in claim 1, wherein the at least one trench is formed through the entire thickness of the substrate.

7. The photodetector as claimed in claim 1, wherein the first sidewall and the second sidewall converge to a contact line.

8. The photodetector as claimed in claim 1, wherein each cell of the plurality of cells comprises a first region of a first conductivity type adjacent to the front side.

9. The photodetector as claimed in claim 8, wherein each cell of the plurality of cells further comprises a second region of a second conductivity type adjacent to the second side.

10. The photodetector as claimed in claim 9, wherein each cell further comprises an intermediate region of the first conductivity type between the first region and the second region.

11. The photodetector device as claimed in claim 10, wherein the intermediate region is spaced apart from at least one of the first region or the second region.

12. The photodetector as claimed in claim 9, wherein each cell further comprises an intermediate region of the second conductivity type between the first region and the second region.

13. The photodetector as claimed in claim 12, wherein the intermediate region at least substantially contacts the first region.

14. The photodetector as claimed in claim 1, wherein each cell further comprises a resistor.

15. The photodetector as claimed in claim 1, further comprising an insulating material in between the first sidewall and the second sidewall of the at least one trench.

16. The photodetector as claimed in claim 1, further comprising a readout circuit electrically coupled to the plurality of cells.

17. The photodetector as claimed in claim 1, further comprising a support carrier coupled to the substrate.

18. A method for forming a photodetector, the method comprising:
providing a substrate having a first side and a second side opposite to the first side, the substrate being adapted to receive light incident on the photodetector on the first side of the substrate;
forming a plurality of cells in the substrate; and
forming at least one trench defined by a first sidewall and a second sidewall, wherein a spacing between the first sidewall and the second sidewall increases in a direction from the first side of the substrate towards the second side,
wherein a respective trench of the at least one trench is arranged in between adjacent cells of the plurality of cells.

19. The method as claimed in claim 18, wherein forming at least one trench comprises etching the substrate anisotropically.

20. The method as claimed in claim 19, wherein etching the substrate anisotropically comprises subjecting the substrate to an alkaline solution.
